(19) United States
(12) Patent Application Publication
(10) Pub. No.: US 2016/0181249 A1
(43) Pub. Date: Jun. 23, 2016

(54) SEMICONDUCTOR STRUCTURES WITH DEEP TRENCH CAPACITOR AND METHODS OF MANUFACTURE

(71) Applicant: International Business Machines Corporation, Armonk, NY (US)

(72) Inventors: Guillaume D. BRIEND, COETMIEUX (FR); Ricardo A. DONATON, Cortlandt Manor, NY (US); Herbert L. HO, New Windsor, NY (US); Donghun KANG, Hopewell Junction, NY (US); Babar A. KHAN, Ossining, NY (US); Xinhui WANG, Poughkeepsie, NY (US); Deepal WEHELLA-GAMAGE, Newburgh, NY (US)

(21) Appl. No.: 14/573,632

(22) Filed: Dec. 17, 2014

(51) Int. Cl. H01L 27/108

(52) U.S. Cl. CPC H01L 27/1087; H01L 27/10802; H01L 27/10826; H01L 27/10829

(57) ABSTRACT

An integrated FinFET and deep trench capacitor structure and methods of manufacture are provided. The method includes forming a plurality of fin structures from a substrate material. The method further includes forming a deep trench capacitor structure, contacting at least selected fin structures. The method further includes forming a liner over the deep trench capacitor structure. The method further includes forming replacement gate structures with the liner over the deep trench capacitor structure protecting the deep trench capacitor structure during deposition and etching processes.

### FIELD OF THE INVENTION

The invention relates to semiconductor structures and methods of manufacture and, more particularly, to an integrated FinFET and deep trench capacitor structure and methods of manufacture.

### BACKGROUND

FinFETs are three dimensional structures which provide excellent scalability. For example, FinFETs rise above the planar substrate, giving them more effective gate width for the same substrate footprint than conventional gate structures. Also, by wrapping the gate around the channel, the FET is fully depleted, so that little current is allowed to leak through the body when the device is in the off state, i.e., thereby providing low gate leakage current. This provides superior performance characteristics, e.g., high on currents due to the larger effective gate width, lower off currents due to the full depletion and less threshold voltage variations due to lower channel doping, resulting in improved switching speeds and power.

FinFETs can be fabricated using, for example, silicon on insulator (SOI) substrates. In SOI technologies, FinFETs can be used with many other devices and structures, and can be fabricated using CMOS technologies, e.g., lithography, etching and deposition methods. However because of the three dimensional structure, integration with other devices and/or structures are difficult and quite challenging. For example, it is a challenge to fabricate deep trench capacitors (eDRAM) with current FinFET fabrication processes.

### SUMMARY

In an aspect of the invention, a method comprises forming a plurality of fin structures from a substrate material. The method further comprises forming a deep trench capacitor structure, contacting at least selected fin structures. The method further comprises forming a liner over the deep trench capacitor structure. The method further comprises forming replacement gate structures with the liner over the deep trench capacitor structure protecting the deep trench capacitor structure during deposition and etching processes.

In an aspect of the invention, a method of forming a deep trench capacitor and a FinFET comprises: patterning semiconductor material to form a plurality of fins along an underlying substrate; segmenting the fins to create a plurality of fin structures with a capping material thereon; forming a deep trench capacitor extending within a buried oxide layer, under the semiconductor material; forming a film of dielectric material over conductive material of the deep trench capacitor; annealing the film of dielectric material thereby hardening the film of dielectric material; and forming replacement gate structures over the plurality of fin structures while protecting the conductor material with the hardened film of dielectric material.

In an aspect of the invention a structure comprises: a plurality of segmented fin structures; a deep trench capacitor extending within a buried oxide layer, under the plurality of segmented fin structures; a hardened film of annealed dielectric material over conductive material of the deep trench capacitor; and replacement gate structures over the plurality of fin structures and at least portions of the hardened film.

### BRIEF DESCRIPTION OF THE SEVERAL VIEWS OF THE DRAWINGS

The present invention is described in the detailed description which follows, in reference to the noted plurality of drawings by way of non-limiting examples of exemplary embodiments of the present invention.

FIG. 1 shows a structure and respective fabrication processes of forming fin structures, amongst other features, according to aspects of the invention;

FIG. 2 shows a structure and respective fabrication processes of forming deep trenches filled with material according to aspects of the invention;

FIG. 3 shows a structure and respective fabrication processes of forming poly material within a recessed portion of the deep trenches according to aspects of the invention;

FIG. 4a shows a structure and respective fabrication processes of capping the poly material within a recessed portion of the deep trenches according to aspects of the invention;

FIG. 4b shows a structure and respective fabrication processes of pad removal according to aspects of the invention;

FIG. 5 shows a structure and respective fabrication processes including forming a liner on the poly material of the deep trenches according to aspects of the invention;

FIG. 6 shows a structure and respective fabrication processes of annealing or hardening the liner, amongst other features, according to aspects of the invention;

FIG. 7 shows a structure and respective fabrication processes of exposing fin structures in preparation for gate replacement processes according to aspects of the invention;

FIG. 8a shows a perspective view of a structure and respective fabrication processes of replacement gate formation according to aspects of the invention; and

FIG. 8b shows a cross sectional view of the structure of FIG. 8a and respective fabrication processes according to aspects of the invention.

### DETAILED DESCRIPTION

The invention relates to semiconductor structures and methods of manufacture and, more particularly, to an integrated FinFET and deep trench (DT) capacitor structure and methods of manufacture. More specifically, the present invention comprises a method of manufacturing an integrated embedded DRAM (eDRAM) (e.g., deep trench capacitor) with an SOI (silicon-on-insulator) FinFET. The processes include a deep trench (DT) post fin integration process that fully encapsulates poly within the deep trench and prevents it from being attacked by subsequent gate and middle of the line (MOL) processes. In addition, the fins are fully protected during the DT formation process by encapsulating them with a combination of dielectric layers and revealing the fins just before the gate dielectric deposition by etching the dielectric layers encapsulating the fins.

More specifically, in the processes described herein, a DT postfin process provides protection over the deep trench to withstand CMP as well as replacement gate, MOL and other processes. For example, in the formation processes described herein, an encapsulation film (e.g., annealed dielectric material liner) is formed after the deep trench is filled with capacitor material (e.g., poly material). The annealed dielectric material liner will encapsulate or protect the capacitor material during subsequent CMP and wet etch processes. In this way, the processes described herein avoid many issues related to the formation of the fin structures after the DT capacitor structure is formed.

The structures described herein, e.g., deep trench capacitor and FinFETs, can be manufactured in a number of ways using a number of different tools. In general, though, the methodologies and tools are used to form structures with dimensions in the micrometer and nanometer scale. The methodologies, i.e., technologies, employed to manufacture the structures described herein have been adopted from integrated circuit (IC) technology. For example, the structures of the present invention are built on wafers and are realized in films of material patterned by photolithographic processes on the top of a wafer. In particular, the fabrication of the structures of the present invention uses three basic building blocks: (i) deposition of thin films of material on a substrate, (ii) applying a patterned mask on top of the films by photolithographic imaging, and (iii) etching the films selectively to the mask.

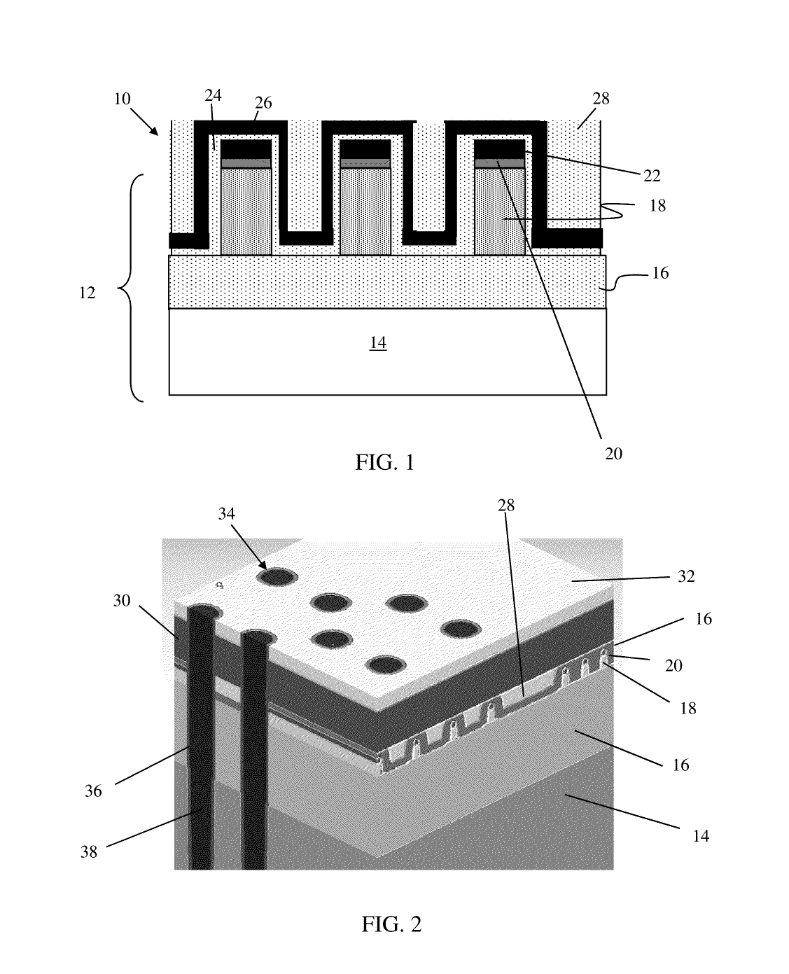

FIG. 1 shows a structure and respective processing steps in accordance with aspects of the invention. The structure 10 of FIG. 1 includes a plurality of fin structures 18 formed from semiconductor material of a SOI substrate 12. In embodiments, the SOI substrate 12 is commercially available and can be fabricated using any conventional processes such as, for example, SiMOX, SMARTCUT or other known techniques. By way of illustrative example, the substrate 12 includes a buried oxide or other insulator layer 16 sandwiched between a wafer 14 and a patterned semiconductor layer (e.g., fin structures) 18. In embodiments, the semiconductor layer can be any semiconductor material such as, for example, Si, SiGe, Ge, GaAs, as well as other III/V or II/IV compound semiconductors or any combinations thereof.

In embodiments, the fin structures 18 can be formed using a sidewall image transfer (SIT) technique. In the SIT technique, for example, a mandrel is formed on the semiconductor layer using conventional deposition, lithography and etching processes. A resist is formed on the mandrel material, and exposed to light to form a pattern (openings). A reactive ion etching (RIE) is performed through the openings to form the mandrels. Spacers are formed on the sidewalls of the mandrels which are preferably material that is different than the mandrels, and which are formed using conventional deposition processes known to those of skill in the art. In embodiments, the spacer material can be an oxide film 20 and a nitride film 22, which will remain on the fin structures 18 during subsequent processing steps. The spacers can have a width which matches the dimensions of the narrow fin structures 18, for example. The mandrels are removed or stripped using a conventional etching process, selective to the mandrel material. An etching is then performed within the spacing of the spacers to form the sub-lithographic features, e.g., fin structures 18. In embodiments, the spacer materials, e.g., oxide film 20 and nitride film 22, will remain on the fin structures 18 during subsequent processes.

In embodiments, the fins can be cut or segmented to form a plurality of fin structures 18. For example, by using a conventional lithography and etching processes, .e.g., wet etch process, portions of each fin can be removed to form a plurality of fin structures 18 along a length or width of the substrate 12. This process will be performed pre-cap removal, e.g., prior to removal of the oxide film 20 and nitride film 22.

Still referring to FIG. 1, a thin oxide material 24 is deposited on the fin structures 18 and exposed surface of the BOX 16. In embodiments, the thin oxide material 24 can be deposited using a conformal deposition process, e.g., molecular layer deposition (MLD), to a thickness of about 3 nm; although other dimensions are also contemplated by the present invention. A nitride material 26 is deposited over the oxide material 24 to a thickness of about 15 nm to 25 nm (depending on the technology node) using a conventional conformal deposition processes, e.g., MLD. The nitride thickness is sufficient to completely fill the space between the logic fins (which are on a tighter pitch), while leaving a space between the fins in the eDRAM arrays which are on a wider pitch. Another oxide material 28 is deposited on the nitride material 26, using high density plasma (HDP) processes or other conformal deposition process known to those of skill in the art. In embodiments, the oxide material 28 can be deposited to a thickness of about 2000 Å; although other dimensions are also contemplated by the present invention. The oxide thickness should be sufficient to completely fill the space between the nitride encapsulated fins in the eDRAM arrays. The structure then undergoes a chemical mechanical planarization (CMP) process, which planarizes the oxide, stopping on the portions of the nitride material at the top of the fins 26. In embodiments, the oxide material 24 and nitride material 26 will protect the fin structures 18 during subsequent processing steps.

As shown in FIG. 2, a hardmask is formed over the planarized oxide material 28 and nitride material 26. The hardmask can be a combination of nitride material 30 and oxide material 32. For example, the nitride layer 30 can be deposited to a thickness of about 1000 Å; whereas, the oxide layer 32 can be deposited to a thickness of about 1 micron. In embodiments, a resist is then formed over the hardmask, which is exposed to energy (light) to form a pattern. An etching process, e.g., reactive ion etching (RIE), is performed through the pattern to form deep trenches 34, aligned with an edge of selected fin structures 18, e.g., between the segments comprising the fin structures 18. In this way, the fin structure 18 can be self aligned with the deep trench and in contact with a polysilicon plug. In embodiments, the deep trenches 34 extend into the BOX layer 16. The resist can then be removed using conventional methods, e.g., oxygen ashing process.

Still referring to FIG. 2, the deep trenches 34 are then filled with material, including a dielectric layer 36 followed by a TiN and poly fill, shown at reference numeral 38. In embodiments, the dielectric layer 36 is a high-k dielectric liner, e.g., hafnium based material or other high-k dielectric material. In alternative embodiments, the dielectric layer 36 can be any insulator material (not limited to a high-k dielectric) deposited to a thickness of about 1 nm to about 3 nm; although other thicknesses are also contemplated by the present invention. A metal layer, e.g., TiN, is then deposited on the dielectric material to a thickness of about 1 nm to about 3 nm; although other thicknesses are also contemplated by the present invention. The remaining portion of the trench is then filled with polysilicon material. (The metal layer and the poly material are both represented by reference numeral 38.) The materials 36 and 38 can be deposited by conventional deposition processes, e.g., atomic layer deposition (ALD). Any excess material can then be removed from the surface by a Reactive Ion Etching (RIE) or CMP process, or a combination of both, for example.

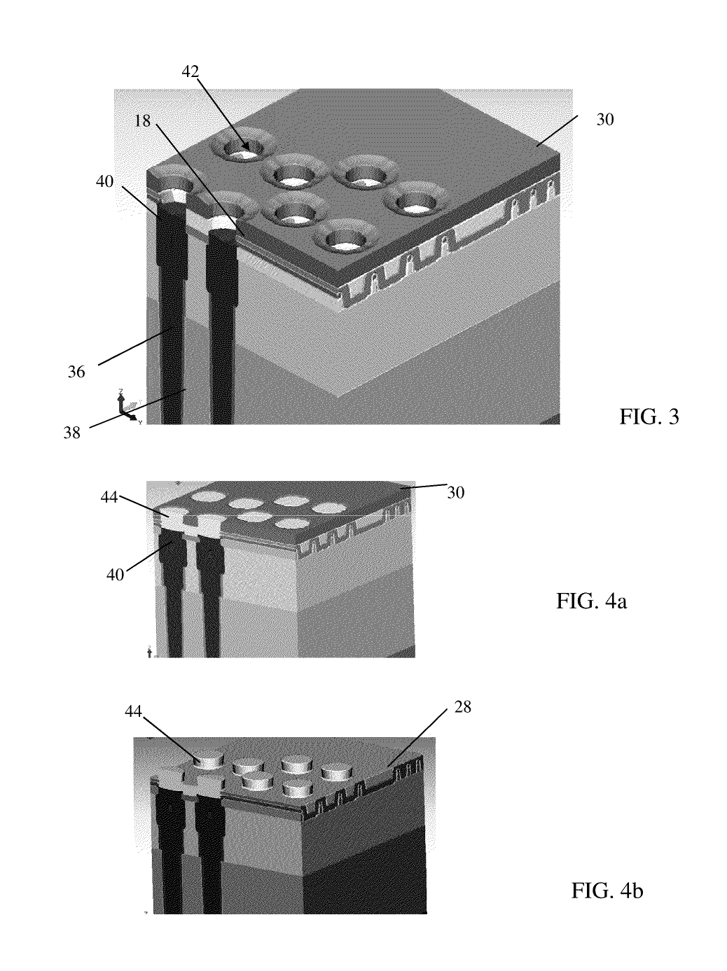

In FIG. 3, the materials 36, 38 are recessed to below an upper surface of the BOX 16. In embodiments, the materials 36, 38 can be recessed by a selective wet etch process and RIE process. After recessing, the upper portion of the deep trench 34 is filled with a poly material 40, which is in contact with selected fin structures 18. In this way, the fin structure 18 can be self aligned with the deep trench and in contact with a polysilicon plug. The poly material 40 is then recessed to an approximate height of the fin structures 18 to form another recess 42. The upper oxide layer (32) and nitride layer (30) of the hard mask are then removed using conventional removal processes, e.g., wet or dry etching processes. Hot phosphoric acid can be used to remove the nitride layer (30). A process that ensures that the hot phosphoric acid does not attack the exposed polysilicon in the deep trench is described in FIGS. 4a and 4b.

As shown in FIG. 4a, the recesses 42 are filled with a capping material 44. In embodiments, the capping material 44 is an oxide material which completely fills the recesses 42. The oxide material can be deposited using a HDP process, followed by a planarization process (e.g., CMP). In alternate embodiments, the capping material 44 can be formed with an oxide spacer deposition process, in which the oxide is deposited onto the sidewalls of the recess 42 and over the poly material 40. In either scenario, the capping material 44 will protect the poly material 40 during the nitride removal process.

In FIG. 4b, the upper nitride material is removed by a selective etching process, leaving the capping material 44 over the poly material 40 (see, e.g., FIG. 4b). In embodiments, the nitride material is removed by a hot phosphoric acid etch (HP) process, which will attack the polysilicon. As such, the capping material 44 will protect the poly material 40 during the HP process.

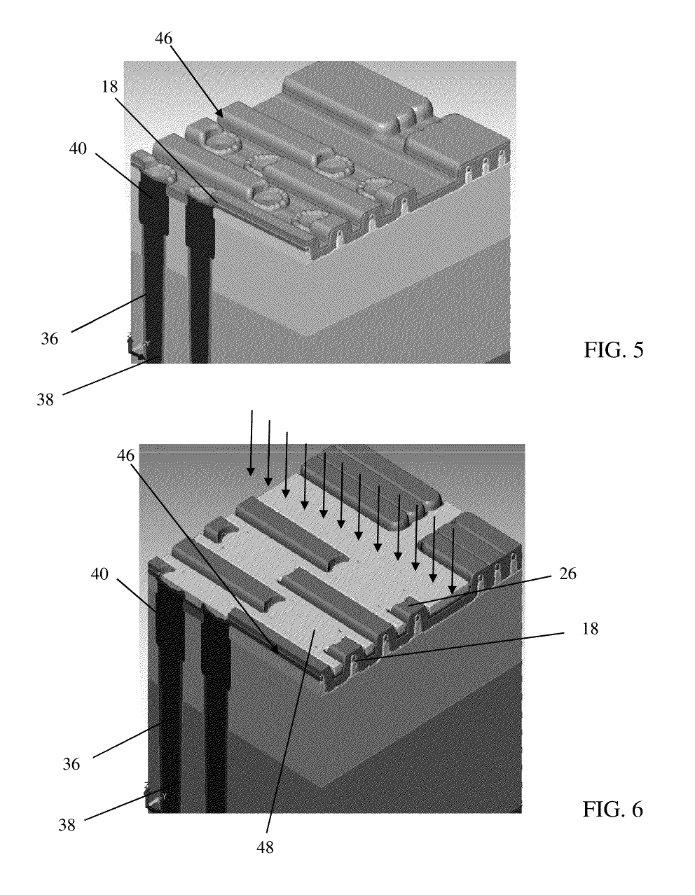

In FIG. 5, the capping material 44 and underlying oxide material (oxide material 28) have been removed to expose the nitride material 26 and the poly material 40. The nitride material 26 and the poly material 40 are then covered with a high-k dielectric liner 46. In embodiments, the high-k dielectric liner 46 can be a hafnium oxide or hafnium silicate. The high-k dielectric liner 46 can be deposited by a conformal deposition process, e.g., chemical vapor deposition (CVD), to a thickness of about 3 nm to 15 nm; although other dimensions are also contemplated by the present invention. The high-k dielectric liner 46 will protect the poly material 40 during subsequent MOL and replacement gate formation processes.

FIG. 6 shows the deposition of an oxide material 48, following by CMP and wet etching processes. In embodiments, the CMP and wet etching processes will planarize the oxide material 48 and remove portions of the high-k dielectric liner 46 to thereby expose a surface of the nitride material 26, e.g., expose a surface of the nitride material 26 over the fin structures 18. In further fabrication processes, additional oxide material 48 and portions of the high-k dielectric liner 46 formed over the fin structures 18 can be pulled down (e.g., recessed) using a wet etch process. In embodiments, the high-k dielectric liner 46 can be pulled down about 5-15 nm, depending on the previous CMP process. It should be understood by those of skill in the art that the high-k dielectric liner 46 will remain over the poly material 40 in order to protect the poly material 40 during subsequent processing steps.

The structure then undergoes a thermal anneal process (represented by the plurality of arrows) to harden the high-k dielectric liner 46. In embodiments, the thermal anneal process can be performed at about 400° C. for about 15 minutes. More specifically, the high-k dielectric liner 46, in some embodiments, can be treated to harden and increase the density by baking (i.e., thermal annealing), irradiative annealing, plasma curing, E-beam curing, and/or UV curing the high-k dielectric liner 46. For example, the high-k dielectric liner 46 may be baked (i.e., thermally annealed) at a temperature of up to about 600° C. (e.g., about 300° C. to about 400° C.) for a period of time of up to about an hour (e.g., about 1 minute to about 1 hour).

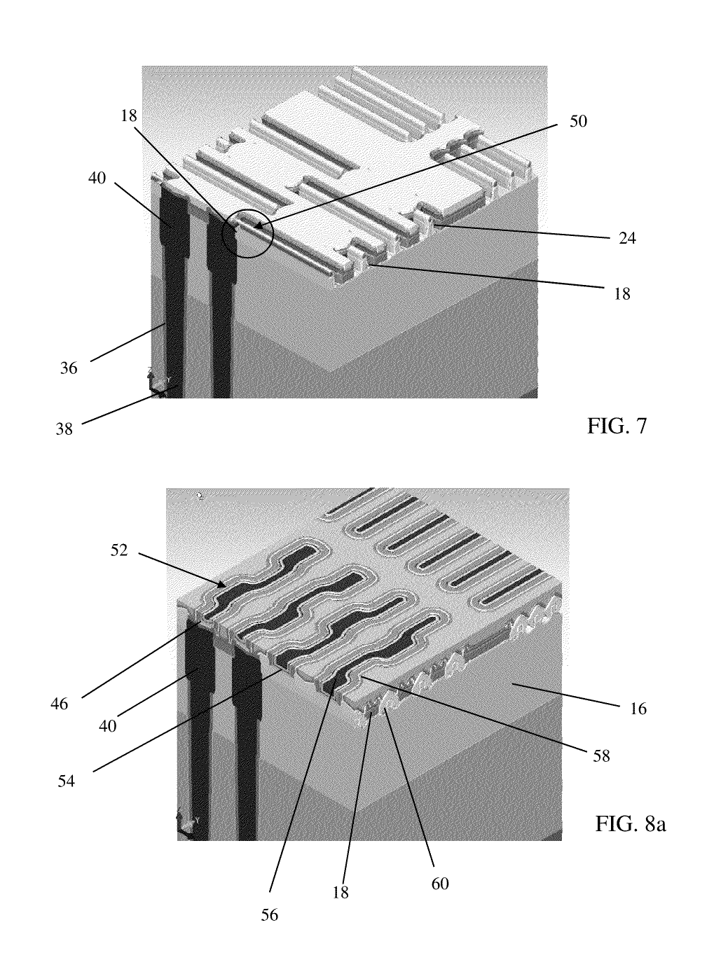

In FIG. 7, the fin structures 18 are exposed, e.g., the nitride material 26 over the fin structures 18 is removed. More specifically, the nitride material 26 is removed, exposing the oxide material 24 formed on the fin structures 18. This process can be performed by a combination of wet (HP) and dry (RIE) processes, with the hardened high-k dielectric liner 46 protecting the poly material 40 that is in contact with the edges of selected fin structures 18 as shown at reference numeral 50. The remaining oxide material (24) is removed by wet etching, which exposes the silicon fins so that they are ready for gate dielectric deposition and the gate process.

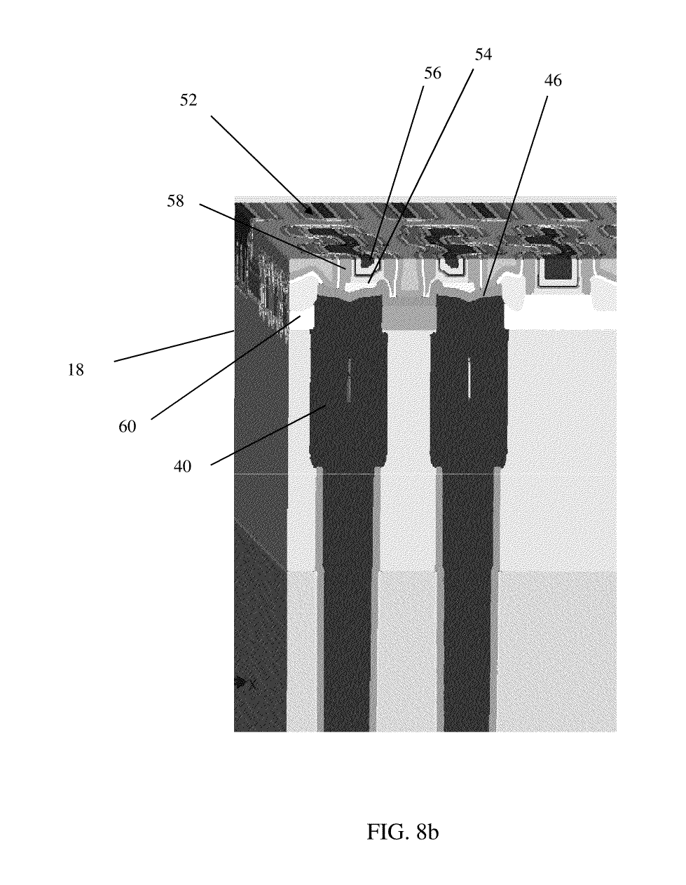

FIG. 8a shows a perspective view of the replacement gate structure and respective fabrication processes. FIG. 8b shows a cross sectional view of the structure of FIG. 8a and respective fabrication processes according to aspects of the invention. As shown representatively in FIGS. 8a and 8b, the oxide material 24, oxide film 20 and nitride film 22 has been removed from the fin structures 18, exposing the semiconductor material. Following the removal of the materials over the fin structures 18, a gate process can be performed to form a metal replacement gate as shown at reference numeral 52. As should be understood the annealed high-k dielectric liner 46 will be very resistant to the RIE and wet etch processes that are used to form the gate and spacer and will keep the poly material 40 within the deep trench fully encapsulated during the entire gate and spacer formation processes.

By way of more specific example, a gate dielectric material 54 is deposited on the fin structures 18 using a conventional gate dielectric deposition process. This is followed by deposition and patterning of amorphous silicon to form the gate structure. This is followed by the spacer formation process, e.g., spacer material such as nitride material 58. The process continues with a source-drain epitaxial growth and then the replacement gate process. In embodiments, the material forming the source and drain 60 can be doped Si or other semiconductor material. For example, the source region can be an N+ epi material; whereas, the drain region can be a P+ epi material. In the replacement gate process, the gate amorphous silicon is exposed by a CMP process and the amorphous silicon removed by an isotropic RIE process. This is followed by a deposition of a metal or metal alloy material(s) 56 engineered with certain work functions to form the gate, itself. The structure can then be planarized to remove any excessive gate material, 5followed by contact and anneal processes known to this of skill in the art.

The methods as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1.-19. (canceled)

20. A structure, comprising:
a plurality of segmented fin structures;
a deep trench capacitor extending within a buried oxide layer, under the plurality of segmented fin structures;
a hardened film of annealed dielectric material over conductive material of the deep trench capacitor; and
replacement gate structures over the plurality of fin structures and at least portions of the hardened film.

21. The structure of claim 20, wherein the deep trench capacitor and an edge of selected fin structures of the plurality of segmented fin structures are self aligned.

22. The structure of claim 20, wherein the deep trench capacitor is filled with a dielectric layer with the conductive material over the dielectric layer.

23. The structure of claim 22, wherein the conductive material is a TiN and poly fill and the dielectric layer is a high-k dielectric liner.

24. The structure of claim 23, wherein the dielectric layer and the conductive material are recessed to below an upper surface of the buried oxide layer.

25. The structure of claim 24, wherein the deep trench capacitor further includes a poly material plug within the recess fowled by the dielectric layer and the conductive material.

26. The structure of claim 25, wherein the poly material plug is recessed to an approximate height of the fin structures.

27. The structure of claim 26, wherein the poly material plug is covered by the hardened film of annealed dielectric material.

28. The structure of claim 27, wherein the hardened film of annealed dielectric material is a high-k dielectric liner.

29. The structure of claim 28, wherein the replacement gate structures comprise a gate dielectric material deposited on the fin structures with an amorphous silicon over the gate dielectric material.

30. A structure, comprising:
a plurality of fin structures from a substrate material;
a deep trench capacitor structure, contacting at least selected fin structures;
a liner over the deep trench capacitor structure; and
replacement gate structures with the liner over the deep trench capacitor structure protecting the deep trench capacitor structure during deposition and etching processes.

31. The structure of claim 30, wherein the liner comprises an annealed high k-dielectric material over the deep trench capacitor structure.

32. The structure of claim 30, wherein the deep trench capacitor structure includes a poly material recessed to a height of approximately the plurality of fin structures.

33. The structure of claim 30, wherein the deep trench capacitor structure is formed within a buried oxide material of a silicon-on-insulator (SOI) substrate.

34. The structure of claim 30, wherein the deep trench capacitor structure comprises:
a deep trench into the buried oxide material;
a recessed dielectric material lining the deep trench with a recessed metal material fill;
recessed poly material on the metal material fill; and
additional poly material, in contact with the selected fin structures.
